(19) United States
(12) Patent Application Publication
(10) Pub. No.: US 2011/0123931 A1
(43) Pub. Date: May 26, 2011

(54) High-precision ceramic substrate preparation process

(75) Inventor: Wen-Hsin Lin, Taipei City (TW)

(73) Assignee: HOLY STONE ENTERPRISE CO., LTD., Taipei City (TW)

(21) Appl. No.: 12/805,720

(22) Filed: Aug. 17, 2010

(30) Foreign Application Priority Data
Nov. 20, 2009 (TW) 098139522

(51) Int. Cl. G03F 7/20

(52) U.S. Cl. 430/314

(57) ABSTRACT

A high-precision ceramic substrate preparation process is disclosed to bond a dry film to a metal layer on a ceramic plate, and then to coat a conductive layer on the metal layer and an anti-etching metal layer on the conductive layer after application of an exposing and developing process to form a predetermined circuit pattern in the dry film, and then to remove the dry film and to etch the metal layer, and then to bond an oxygen-free tape, which is prepared from a compound of ceramic powder, glass powder and pasting agent, to the conductive layer, and then to sinter the oxygen-free tape in an oxygen-free sintering furnace into a retaining wall, and then to coat an anti-oxidation bonding layer on the surface of the conductive layer.

This application claims the priority benefit of Taiwan patent application number 098139522, filed on Nov. 20, 2009.

### BACKGROUND OF THE INVENTION

1. Field of the Invention

The present invention relates to the fabrication of ceramic substrates and more particularly, to a high-precision ceramic substrate preparation process, which employs coating, exposing and developing techniques instead of conventional printing technique. The high-precision ceramic substrate preparation is to bond an oxygen-free green sheet prepared from a compound consisting of low temperature cofired ceramics (LTCC) or aluminum oxide (Al₂O₃), glass powder and pasting agent after formation of a metal layer and a conductive layer on a ceramic plate, and then to sinter the oxygen-free tape into a retaining cavity prior to coating of an anti-oxidation bonding layer on the surface of the conductive layer, avoiding oxidation of the conductive layer and facilitating application of further bonding or electroplating process.

2. Description of the Related Art

Following fast development of technology and subject to the factor that people are seeking for high quality of life, the requirements for the application characteristics of products are critical. In consequence, the use of newly developed materials becomes a requisite for the fabrication of certain products. In order to achieve better transmission efficiency and smaller product size, IC package manufacturers have been investing a lot of money to improve their manufacturing processes for the fabrication of electronic component parts (for example, mobile telephone or mini notebook computer). Nowadays, ceramic substrates have been intensively used to substitute for conventional substrates for the advantages of excellent electrical insulating properties, high chemical stability, better electromagnetic properties, high hardness, high thermal conductivity, high wearproof characteristics and high temperature resistance.

However, a ceramic substrate is thermal conductive. When using a ceramic substrate for the fabrication of LED products, the problem of heat dissipation must be settled. Radiation fin and heat sink means are commonly used for quick dissipation of waste heat. Further, light cup means may be used to control the direction of light emission, avoiding dispersion of emitted light. Direct formation of a light cup on a ceramic substrate can simplify the manufacturing process and save the molding cost. Ceramic materials are commonly used for making a light cup.

Conventional ceramic substrates may be prepared from aluminum nitride (AlN), aluminum oxide (Al₂O₃) or low temperature cofired ceramics (LTCC). Sintering of aluminum nitride is to be performed in a vacuum furnace. Sintering of aluminum oxide and low temperature cofired ceramics (LTCC) can be performed in a regular sintering furnace. However, when sintering a light cup on a ceramic substrate in a regular sintering furnace, the circuits on the ceramic substrate may be oxidized. When this problem occurs, it will be difficult to coat a metal layer on the ceramic substrate or to bond a metal layer to the ceramic substrate. Even if a metal layer is coated on or bonded to the ceramic substrate, it may drop from the ceramic substrate easily. Due to the aforesaid problems, selection of material for the light cup is critical. Different materials may be needed to fit different manufacturing processes, complicating the fabrication of LED products.

Therefore, it is desirable to provide a high-precision ceramic substrate preparation process that eliminates the aforesaid problems.

### SUMMARY OF THE INVENTION

The present invention has been accomplished under the circumstances in view. It is one object of the present invention to provide a high-precision ceramic substrate preparation process, which prevents dropping of coated or bonded metal layers, assures product quality, and saves the manufacturing cost.

To achieve this and other object of the present invention, a high-precision ceramic substrate preparation process is to form a metal layer and a conductive layer on a ceramic plate subject to a predetermined circuit pattern, and then to bond an oxygen-free tape, to the surface of the conductive layer, and then to sinter the oxygen-free tape into a retaining wall, and then to coat an anti-oxidation bonding layer on the surface of the conductive layer. The oxygen-free tape is prepared from a compound consisting of low temperature cofired ceramics (LTCC) or aluminum oxide (Al₂O₃), glass powder and pasting agent. Thus, the invention prevents oxidation of the conductive layer during the co-firing process, avoiding formation of defective product and assuring product quality.

### BRIEF DESCRIPTION OF THE DRAWINGS

FIG. 1 is a high-precision ceramic substrate preparation process flow chart in accordance with a first embodiment of the present invention.

FIG. 2 is a schematic drawing illustrating the fabrication of a high-precision ceramic substrate in accordance with the first embodiment of the present invention (I).

FIG. 3 is a schematic drawing illustrating the fabrication of a high-precision ceramic substrate in accordance with the first embodiment of the present invention (II).

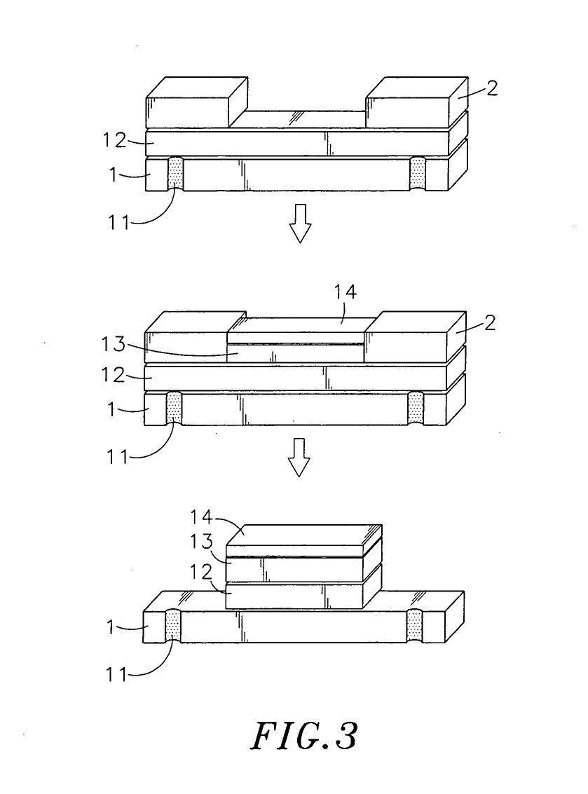

FIG. 4 is a schematic drawing illustrating the fabrication of a high-precision ceramic substrate in accordance with the first embodiment of the present invention (III).

FIG. 5 is a schematic drawing illustrating the fabrication of a high-precision ceramic substrate in accordance with a second embodiment of the present invention.

FIG. 6 is a high-precision ceramic substrate preparation process flow chart in accordance with the second embodiment of the present invention.

### DETAILED DESCRIPTION OF THE PREFERRED EMBODIMENT

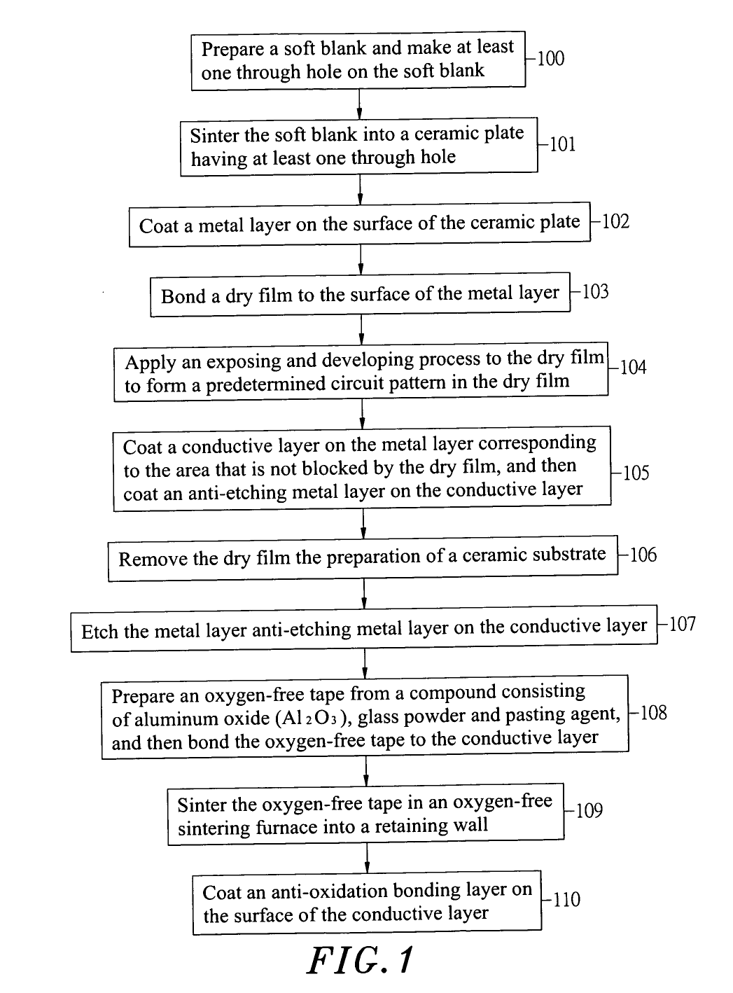

Referring to FIGS. 1˜4, a high-precision ceramic substrate preparation process of the present invention employs coating and high accuracy exposure/etching techniques for the preparation of high-precision ceramic substrates, instead of conventional printing technology. According to the present invention, a soft blank is obtained from, for example, AlN (aluminum nitride) or Al₂O₃ (aluminum oxide), and then punched to provide holes. The soft blank is then sintered into a ceramic plate 1 having at least one through hole 11. Thereafter, a metal layer 12 is coated on the surface of the ceramic plate 1. The metal layer 12 can be prepared from one of the alloys of Ni/Cr/Si+Cu, Fe/Co or Fe/Co/Ni, having a thickness about 0.15 μm˜0.5 μm.

Thereafter, a dry film 2 is bonded to the metal layer 12, and then photolithography is employed to let the dry film 2 receive a exposing and developing process, so that a part of the dry film 2 is removed from the metal layer 12 and a predetermined circuit pattern is left in the dry film 2. Thereafter, a coating technique is employed to coat a conductive layer 13 on the metal layer 12 corresponding to the area that is not blocked by the dry film 2, i.e., corresponding to the circuit pattern. The conductive layer 13 can be prepared from copper, having a thickness about 50 μm˜75 μm. Thereafter, an anti-etching metal layer 14 is coated on the conductive layer 13. The anti-etching metal layer 14 can be prepared from silver or gold, having a thickness about 0.0 μm˜0.1 μm. Thereafter, remove the dry film 2, and then etching the metal layer 12 with an etching solution (ferro chloride or copper chloride), leaving a patterned circuit on the ceramic plate 1. If any residual anti-etching metal layer 14 is left, a chemical is used to remove the residual anti-etching metal layer 14 from the conductive layer 13.

Thereafter, an oxygen-free tape 3 is bonded to the conductive layer 13 by means of a hydraulic press. The oxygen-free tape 3 is prepared from a compound consisting of low temperature cofired ceramics (LTCC) or aluminum oxide (Al₂O₃), glass powder and pasting agent. The low temperature cofired ceramics (LTCC)/aluminum oxide (Al₂O₃), glass powder and pasting agent are prepared subject to a predetermined ratio. The pasting agent can be polyacetones, copolymer of lower alkyl acrylates or methacrylates that can be sintered under a vacuum status. When sintering the blank thus obtained in an oxygen-free sintering furnace, the oxygen-free tape 3 forms a retaining wall 31. Thereafter, an anti-oxidation bonding layer 4 is coated on the surface of the conductive layer 13. The anti-oxidation bonding layer 4 can be prepared from gold, silver or nickel.

Referring to FIGS. 1˜4 again, the high-precision ceramic substrate preparation process comprises the steps of:
(100) Prepare a soft blank and make at least one through hole on the soft blank;
(101) Sinter the soft blank into a ceramic plate 1 having at least one through hole 11;
(102) Coat a metal layer 12 on the surface of the ceramic plate 1;
(103) Bond a dry film 2 to the surface of the metal layer 12;
(104) Apply an exposing and developing process to the dry film 2 to form a predetermined circuit pattern in the dry film 2;
(105) Coat a conductive layer 13 on the metal layer 12 corresponding to the area that is not blocked by the dry film 2 and then coat an anti-etching metal layer 14 on the conductive layer 13;
(106) Remove the dry film 2;
(107) Etch the metal layer 12;
(108) Prepare an oxygen-free tape 3 from a compound consisting of aluminum oxide (Al₂O₃), glass powder and pasting agent, and then bond the oxygen-free tape 3 to the conductive layer 13;
(109) Sinter the oxygen-free tape 3 in an oxygen-free sintering furnace into a retaining wall 31; and
(110) Coat an anti-oxidation bonding layer 4 on the surface of the conductive layer 13.

Further, the metal layer 12 can be obtained from titanium and coated on the surface of the ceramic plate 1 by a coating technique. Alternatively, the metal layer 12 can be formed by means of applying a nano-sized surfactant to modify the surface of the ceramic plate 1 and then coating a layer of nickel, chrome, gold or silver on the modified surface of the ceramic plate 1. Further, coating of the metal layer 12, the conductive layer 13, the anti-etching metal layer 14 and the anti-oxidation bonding layer 4 can be done by means of vacuum coating, chemical vapor deposition, sputter deposition or chemical plating. Because the coating of metal layer 12, the conductive layer 13, the anti-etching metal layer 14 and the anti-oxidation bonding layer 4 is of the known art, no further detailed description in this regard is necessary.

After finish of the aforesaid procedure, further resistor, capacitor or other electronic component installation procedure can then be performed. Further, because sintering of the oxygen-free tape 3 is done in an oxygen-free sintering furnace, the surface of the conductive layer 13 is kept from contact of oxygen, avoiding oxidation of the copper material of the conductive layer 13. If the copper material of the conductive layer 13 is oxidized into copper oxide, the metal layer coated on it or soldered thereto may drop easily, resulting into defective product. By means of the application of oxygen-free sintering, the invention eliminates this problem, improves the product quality, and greatly reduces the manufacturing cost.

Further, the anti-oxidation bonding layer 4 is coated on the surface of the conductive layer 13 after sintering of the oxygen-free tape 3 into a retaining wall 31. After wire bonding and flip chip bumping or chip bonding, the retaining wall 31 blocks the emitted light from the chip, limiting the emitting direction of the LED thus made as designed.

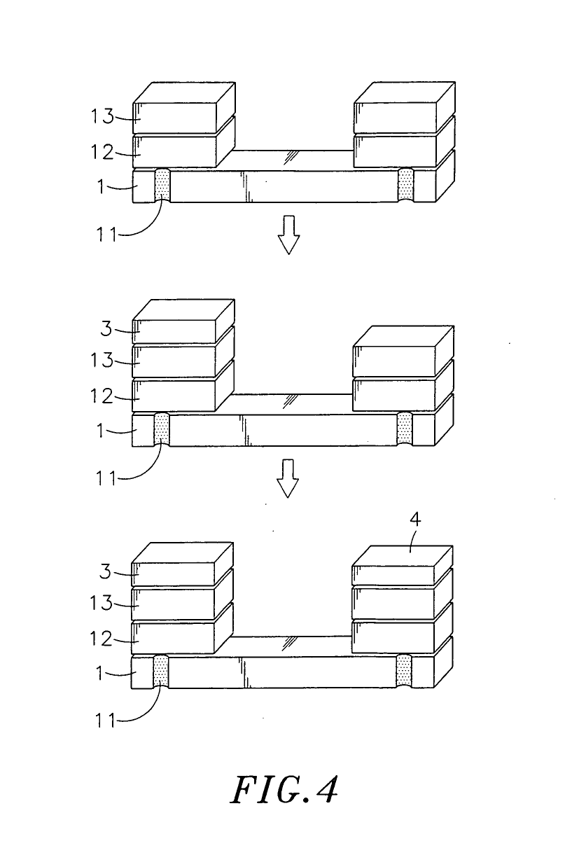

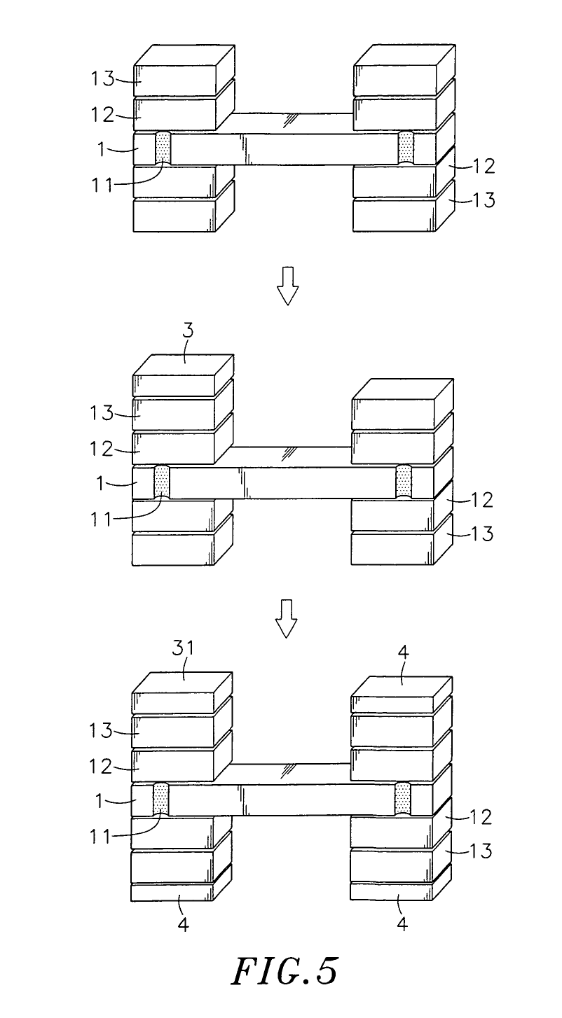

Referring to FIG. 5 and FIG. 4 again, the structure of metal layer 12, conductive layer 13, retaining wall 31 and anti-oxidation bonding layer 4 can be formed on one side of the ceramic plate 1, as shown in FIG. 4. Alternatively, the ceramic plate 1 structure of metal layer 12, conductive layer 13, retaining wall 31 and anti-oxidation bonding layer 4 can be formed on each of the two opposite sides of the ceramic plate 1, as shown in FIG. 5. In this case, each through hole 11 of the ceramic plate 1 is coated with a conducting metal that electrically connects the two structures of metal layer 12, conductive layer 13, retaining wall 31 and anti-oxidation bonding layer 4.

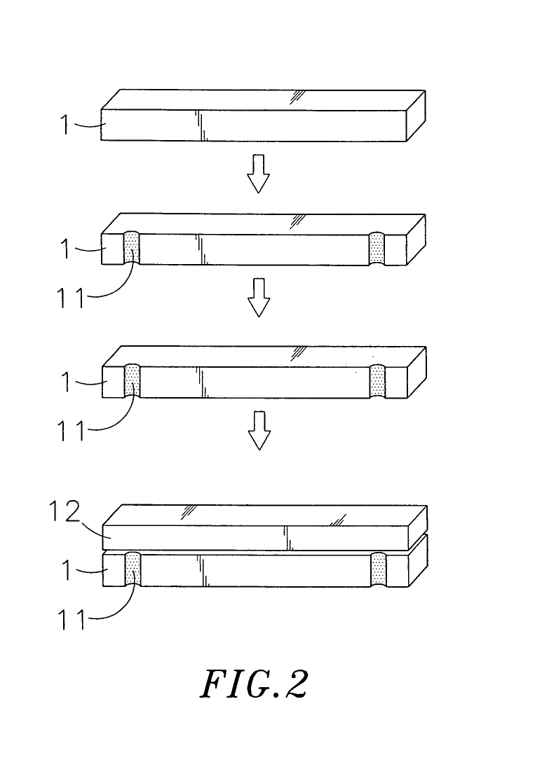

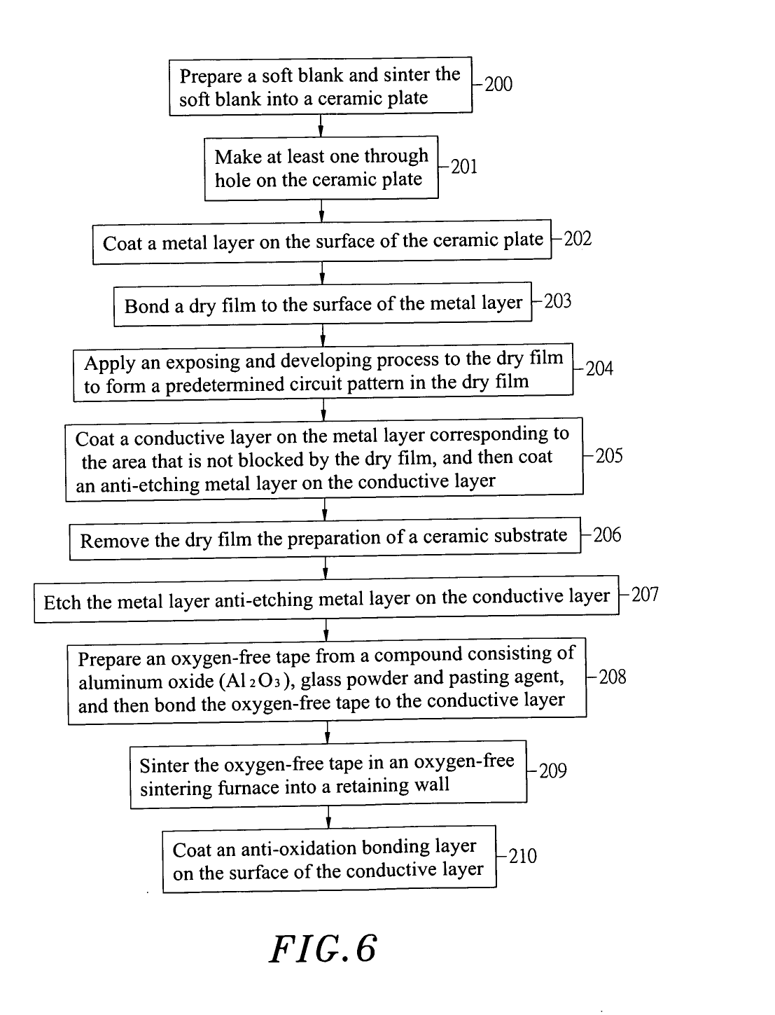

Referring to FIGS. 1, 2 and 6, a high-precision ceramic substrate preparation process in accordance with a second embodiment of the present invention comprises the steps of:
(200) Prepare a soft blank and sinter the soft blank into a ceramic plate 1;
(201) Make at least one through hole 11 on the ceramic plate 1;
(202) Coat a metal layer 12 on the surface of the ceramic plate 1;
(203) Bond a dry film 2 to the surface of the metal layer 12;
(204) Apply an exposing and developing process to the dry film 2 to form a predetermined circuit pattern in the dry film 2;
(205) Coat a conductive layer 13 on the metal layer 12 corresponding to the area that is not blocked by the dry film 2 and then coat an anti-etching metal layer 14 on the conductive layer 13;
(206) Remove the dry film 2;
(207) Etch the metal layer 12;
(208) Prepare an oxygen-free tape 3 from a compound consisting of aluminum oxide (Al₂O₃), glass powder and pasting agent, and then bond the oxygen-free tape 3 to the conductive layer 13;
(209) Sinter the oxygen-free tape 3 in an oxygen-free sintering furnace into a retaining wall 31; and
(210) Coat an anti-oxidation bonding layer 4 on the surface of the conductive layer 13.

As stated above, the soft blank can be obtained from AlN (aluminum nitride) or Al₂O₃ (aluminum oxide), and then punched to provide at least one through hole 11 prior to sintering into a ceramic plate. Alternatively, the soft blank can be sintered into a ceramic plate and then a laser technique is employed to make at least one through hole 11 on the ceramic plate.

In conclusion, the invention provides a ceramic substrate preparation process, which is to form a metal layer 12 and a conductive layer 13 on a ceramic plate 1 subject to a predetermined circuit pattern, and then to bond an oxygen-free tape 3, which is prepared from a compound consisting of low temperature cofired ceramics (LTCC) or aluminum oxide (Al₂O₃), glass powder and pasting agent, to the surface of the conductive layer 13 and then to sinter the oxygen-free tape 3 into a retaining wall 31, and then to coat an anti-oxidation bonding layer 4 on the surface of the conductive layer 13. The invention prevents oxidation of the conductive layer 13 into copper oxide during the co-firing process, avoiding formation of defective product and assuring product quality.

Although particular embodiments of the invention had been described in detail for purposes of illustration, various modifications and enhancements may be made without departing from the spirit and scope of the invention. Accordingly, the invention is not to be limited except as by the appended claims.

What the invention claimed is:

1. A high-precision ceramic substrate preparation process, comprising the steps of:
(a) preparing a ceramic plate and coating a metal layer on the surface of said ceramic plate;
(b) bonding a dry film to the surface of said metal layer;
(c) applying an exposing and developing process to said dry film to form a predetermined circuit pattern in said dry film;
(d) coating a conductive layer on said metal layer and then coating an anti-etching metal layer on said conductive layer;
(e) removing said dry film;
(f) etching said metal layer;
(g) preparing an oxygen-free tape from a compound consisting of ceramic powder, glass powder and pasting agent, and then bond said oxygen-free tape to said conductive layer; and
(h) sintering said oxygen-free tape in an oxygen-free sintering furnace into a retaining wall.

2. The high-precision ceramic substrate preparation process as claimed in claim 1, wherein said ceramic plate is obtained by means of preparing a soft blank from aluminum nitride or aluminum oxide and then making at least one through hole on said soft blank and then sintering said soft blank into said ceramic plate.

3. The high-precision ceramic substrate preparation process as claimed in claim 1, wherein said ceramic plate is obtained by means of preparing a soft blank from aluminum nitride or aluminum oxide and then sintering said soft blank into a ceramic plate and then applying a laser technique to make at least one through hole on the ceramic plate.

4. The high-precision ceramic substrate preparation process as claimed in claim 1, further comprising a sub-step of removing a part of said dry film corresponding to said circuit pattern after application of said exposing and developing process to said dry film and before coating of said conductive layer on said metal layer.

5. The high-precision ceramic substrate preparation process as claimed in claim 1, wherein said conductive layer is coated on said metal layer corresponding to the area that is not blocked by said dry film.

6. The high-precision ceramic substrate preparation process as claimed in claim 1, further comprising a sub-step of coating an anti-oxidation bonding layer on said conductive layer prior to removal of said dry film.

7. The high-precision ceramic substrate preparation process as claimed in claim 1, further comprising step (I) coating an anti-oxidation bonding layer on said conductive layer after sintering of said oxygen-free tape into said retaining wall.

8. The high-precision ceramic substrate preparation process as claimed in claim 7, wherein said anti-oxidation bonding layer is selected from the group consisting of gold, silver and nickel.

9. The high-precision ceramic substrate preparation process as claimed in claim 7, wherein said ceramic powder is selected from the group consisting of low temperature cofired ceramic and aluminum oxide.

10. The high-precision ceramic substrate preparation process as claimed in claim 7, wherein said pasting agent is selected from the group consisting of polyacetones, copolymer of lower alkyl acrylates and methacrylates.

11. The high-precision ceramic substrate preparation process as claimed in claim 1, wherein said metal layer is prepared from the group consisting of Ni/Cr/Si+Cu, Fe/Co and Ce/Co/Ni alloys.

12. The high-precision ceramic substrate preparation process as claimed in claim 1, wherein said ceramic plate has one side thereof coated with said metal layer for the bonding of said dry film.

13. The high-precision ceramic substrate preparation process as claimed in claim 1, wherein said ceramic plate has each of two opposite sides thereof coated with said metal layer for the bonding of said dry film.
